(19) United States
(12) Patent Application Publication
(10) Pub. No.: US 2004/0187307 A1
(43) Pub. Date: Sep. 30, 2004

(54) Heat sink

(76) Inventor: Chee Tieng Wong, Sungai Petani (MY)

Correspondence Address: MERCHANT & GOULD PC, P.O. BOX 2903, MINNEAPOLIS, MN, 55402-0903, US

(21) Appl. No.: 10/462,325

(22) Filed: Jun. 16, 2003

Related U.S. Application Data
(62) Division of application No. 10/172,578, filed on Jun. 13, 2002.

(30) Foreign Application Priority Data
Jun. 15, 2001 (MY) PI 20012831

(51) Int. Cl. H05K 3/30

(52) U.S. Cl. 29/832

(57) ABSTRACT

A heat sink is manufactured by forming a fin 2 for dissipating heat by separating a length of material from a substrate 1 while leaving the proximal end attached to the substrate 1. The fins are cut from the substrate by stamping process using the stamping single or progressive die tooling cutting the substrate 1 along dotted line 16. The heat sink is a unitary construction, with the fins 2 being integrally formed with the substrate 1.

### BACKGROUND OF THE INVENTION

The present invention relates to heat sinks and to a method of forming the same. More particularly, but not exclusively, the present invention relates to an improved method of forming heat dissipating fins of a heat sink.

Heat sinks are well known components used, for example, for dissipating heat from Electronic circuitry, CPUs (computers) and microprocessors in order to cool the components to enable them to function consistently and properly. Heat sinks are often used in conjunction with printed circuit boards which are found in electronic equipment such as television sets and audio amplifiers. There are many types of conventional heat sinks.

One of the most widely used heat sink is extruded heat sink. It is well know to manufacture the extruded heat sink by extruding aluminium, through a complex shaped die to produce a section. Extrusion limits, such as the fin height-to-gap and fin thickness, usually dictate the flexibility in design options. Typically fin height-to-gap aspect ratio of up to 6 and minimum fin thickness of 1.3 mm, are attainable with a standard extrusion. A 10 to 1 aspect ratio and a fin thickness of 0.8 mm can only be achieved with special die design features. However, as the aspect ratio increases, the extrusion tolerance is compromised. Also, extrusion equipment is expensive, the process slow, Further, in order that it can be made by an extrusion process, a heat sink must be made from aluminium, and other materials cannot be used.

Another conventional type of heat sink is folder type heat sink that consists of a base to which a continuous corrugated fin sheet is attached. A plurality of corrugations are formed, which are elongate, adjacent corrugations having the appearance of oppositely facing slots. To attach the corrugated sheet to the base portion, square slots are formed in the corrugation. The corrugated sheet is then slotted in to the base which is extruded so as to have square cross section ridges which are inserted into the slot holes. To ends of the ridges are then stamped flat to hold the corrugated sheet on to the extruded base. The corrugations thus form fins of the heat sink. One disadvantage of such an arrangement is that the corrugated sheet which forms the fins forms a heat trap between alternate pairs of fins.

In another type of conventional heat sink the fins are formed from a numbers of separate sheets of materal which are pressed to form a U-shaped fin. The fins are the riveted to an extruded aluminium base or sheet metal piece using two or more rivets. Such an arrangement is disadvantageous in that the additional manufacturing step of applying the rivets is necessary, and further in that the rivets may work lose, reducing the effectiveness of the heat sink.

### SUMMARY OF THE INVENTION

It is an object of the present invention to provide a heat sink which provides improved heat dissipation.

It is another object of the present invention to provide an improved method of forming the fins to achieve maximum fin height-to-gap aspect ratio and to reduce the fin thickness to as thin as 0.2 mm. The improved method is less expensive, faster and more flexible, and which results in higher cooling capacity and more reliable heat sinks.

According to a first aspect of the present invention, there is provided a method of forming a heat sink, including forming a fin for dissipating heat by separating a thin length of material from a substrate while leaving the proximal end attached to the substrate. Such a method may allow a heat sink to be formed from a unitary sheet of material. The fins are an integral part of the substrate and therefore do not need to be attached to a base(As the folder type or U-fin heat sink does), so there are no joints which could reduce conduction of heat or deteriorate with rough handling and/or ageing. Fins may be produced by cutting thin lengths of material from the substrate.

The fin may be arcuate in configuration.

The fin may extend generally perpendicularly to the plane of the substrate. This may be advantageous as it allows heat to escape from a plurality of fins as it rises between the fins.

A ridge may be formed in the surface of the substrate as a result of the cutting process to form the fin. The ridge may form the distal end of the fin.

The fin may be formed by the stamping process using the single die tooling or a progressive die tooling.

The method may typically be used to form a plurality of the very fine fins up to 0.2 mm in thickness on the substrate. A plurality of fine fins that provide larger surface area expose to the air stream will provide improved heat dissipation.

The plurality of fins may be formed in a series of spaced apart rows. The space between the adjacent fins can be minimised to achieve the maximum fin height-to-gap aspect ratio (20 to 40) thus increase the surface area for better cooling capacity. The spacing apart of the rows may allow improved air circulation, which may also increase heat dissipation.

According to a second aspect of the present invention there is provided a heat sink having a substrate and a plurality of fins for dissipating heat integrally formed therewith. By forming the fins integrally with the heat sink main body, a unitary structure is formed.

Each fin may be a single thin layer of material extending from the substrate. By forming the fins as single layers, no heat is trapped within a single fin, and heat dissipation may be improved.

The heat sink may comprise aluminium or copper, and may consist of only one of aluminium and copper. With prior art extruded heat sinks, only aluminium could be used.

### BRIEF DESCRIPTION OF THE DRAWINGS

For a better understanding of the present invention, embodiments will now be described by way of example, with reference to the accompanying drawings, in which:

FIG. 1 shows a perspective view of a fully formed heat sink in accordance with the present invention;

FIG. 2 shows a side plan view of a heat sink during manufacture thereof;

FIG. 3 shows an overhead plan view of the heat sink of FIG. 1;

FIG. 4 shows a side elevational view of the heat sink of FIG. 1 in completed form;

FIG. 5 shows a front elevational view of the heat sink of FIG. 1 in completed form;

FIG. 6 shows a cross section taken along the line A-A of FIG. 3;

FIG. 7 shows a front elevational view of a heat sink according to a second embodiment of the present invention;

FIG. 8 shows a front elevational view of a heat sink according to a third embodiment of the present invention;

FIG. 9 shows a front elevational view of a heat sink according to a fourth embodiment of the present invention; and

FIG. 10 shows a side elevational view of the heat sink of FIG. 9.

### DESCRIPTION OF THE EMBODIMENTS

Throughout the drawings, the same reference numerals are generally used to designate like elements.

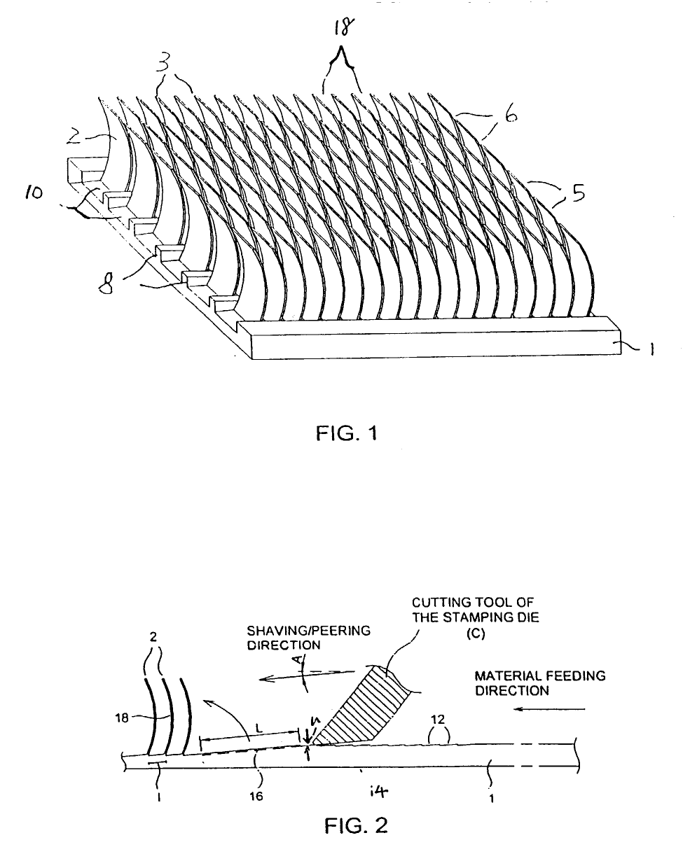

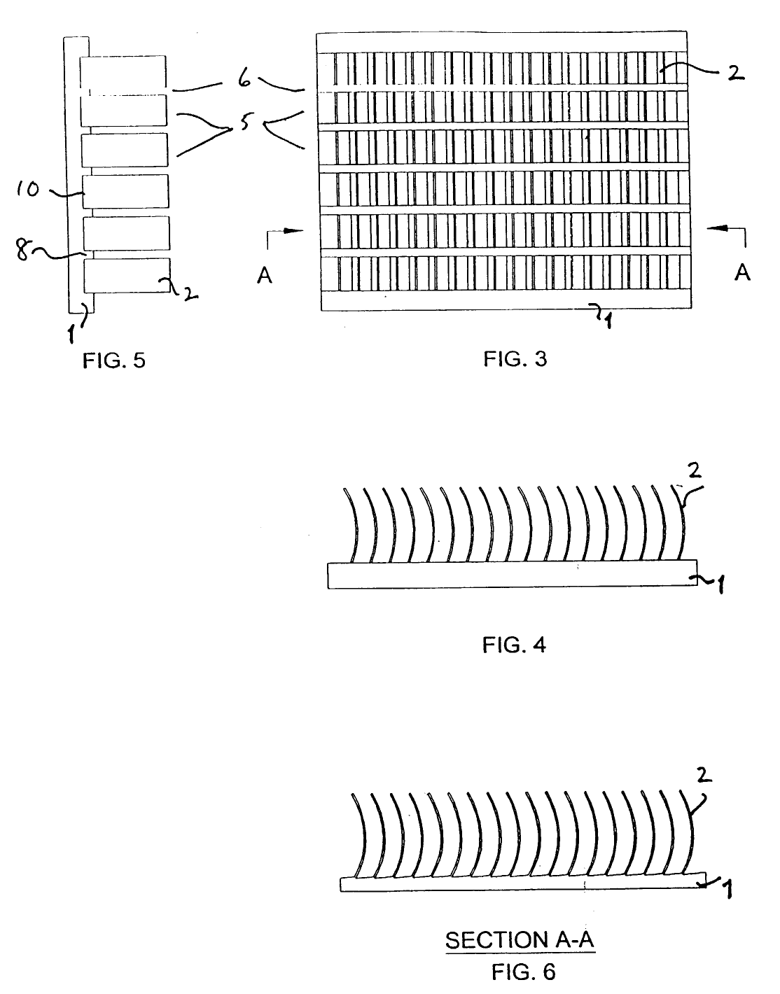

FIGS. 1 to 6 show a first embodiment of the present invention. The heat sink comprises a base or substrate 1, being a block of metal such as aluminium or copper. Layers of the substrate 1 are peeled or shaved away successively in order to form heat dissipative fins 2. The fins 2 may be formed in a series of columns 3 and rows 5. The fins 2 of each column 3 may be formed simultaneously. The rows 5 of fins 2 are separated by a gap 6. Between the rows 5 of fins 2 a rib 8 is present. Between each rib 8 is a groove 10, which is formed as the fins 2 are cut from the substrate 1.

The fins 2 are arcuate. The arc of each fin 2 illustrated represents approximately ⅛ of a circle. The arc profile depends on the design of the tool that forms the fins 2, and the thickness and height of the fins 2.

FIG. 2 shows how a heat sink is formed from substrate 1. Initially, the substrate 1 is a cuboid.

A cutting tool C of a stamping die tooling engages the substrate 1 to form the fin 2 from the substrate 1. The substrate 1 is fed into the stamping tool C manually or by using a material feeder (not shown). The feeding pitch corresponding to each stroke of the press machine may vary depending on the requirements of the tooling as well as the required thickness of the fins, fin height and pitch between the fins of the heatsink.

To facilitate the shaving/peeling process to form the fins 2 at the initial stage of the shaving process, a series of grooves 12 may be coined/formed on the surface of the substrate 1. The substrate 1 is then progressed toward the shaving/peeling portion of the cutting tool. Once the shaving and peeling portion of the cutting tool C contacts the substrate 1, material will start peeling from the surface of the substrate 1. The first few fins will directly peel off from the substrate 1 until the proximal end of the fins is able remain connected to the substrate 1, where the first column of fins is formed. The subsequent columns of fins will then be continually formed by the stamping die tool as the substrate 1 is fed forward by a specific distance on by every stroke of the press machine. These subsequent fins will have a thickness corresponding to the height “h” of the ridge 12. The ridge 12 will form the distal end of the fin 2.

The shaving/peeling advancement direction A of the cutting tool C may vary from approximately 2° to 20° depending on the required fin thickness and height as well as the pitch between the fins. The fins will be shaved/peeled along the dotted lines 16 separating a length “L” of substrate material from the main body of the substrate 1 at a distance “1” from the previously formed fins, the distance “1” determining the spacing or pitch between adjacent fins once formed. The proximal end of the fin 2 remains connected to the main body of the substrate 1 after the shaving and peeling process. During the final phase of movement of the cutting tool C, the fin 2 is peeled away from the main body of the substrate 1 so that it lies generally perpendicular thereto.

This process will create a long strip of substrate 1 with the fins on the surface of the substrate 1. A cutting tool or machine may be engaged later to cut the substrate 1 into small piece with a specific number of columns of fins required by the heat sink.

The pitch 18 between the columns of fins 2 is determined by the distance 1, and is chosen according to the heat dissipation requirements of the heat sink.

The gap 6 between the rows 5 of fins 2 is also chosen according to the heat dissipation requirements of the heat sink.

The thickness (corresponding to h) of each fin 2 can also be selected according to the requirements of an individual heat sink.

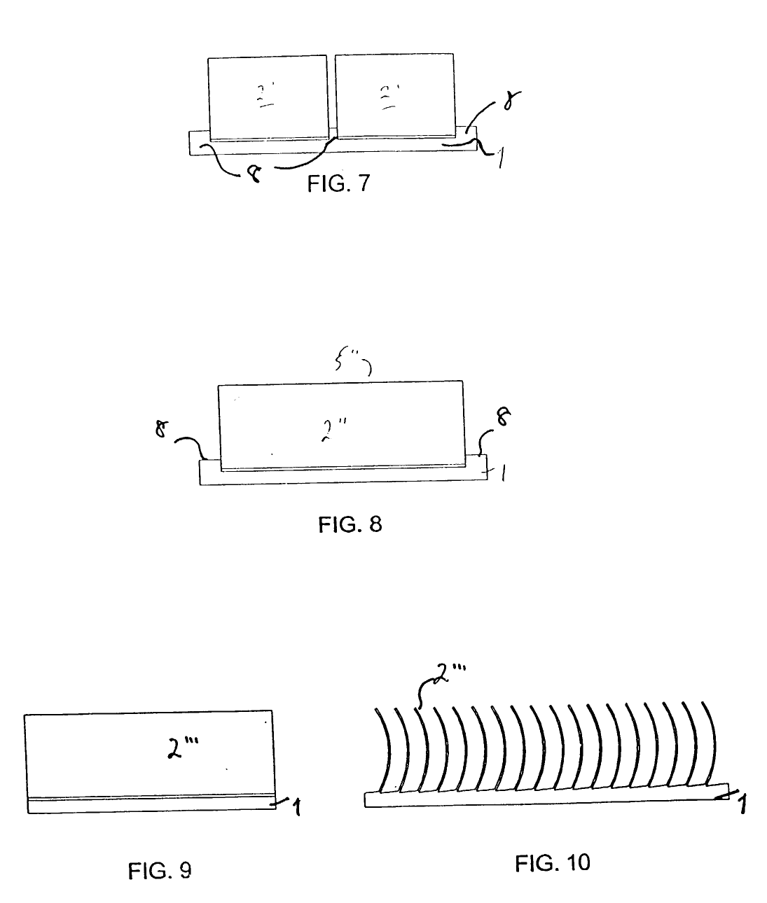

FIG. 7 shows a heat sink according to a second embodiment of the present invention having only two rows 5′ of fins 2′. The fins 2′ of each row 5′ are wider than the fins 2 of the first embodiment.

FIG. 8 shows a third embodiment of the invention wherein a single row 5″ of fins 2″ is formed.

FIG. 9 shows a fourth embodiment, which is small modification of the third embodiment. In the fourth embodiment the fins 2′″ are formed across the full width of the substrate 1 rather than leaving a rib 8 at each side, as in the first, second and third embodiments.

FIG. 10 is a side elevational view of the heat sink of FIG. 9.

The pitch 18 of the fins 2 according to the embodiments of the present invention and the thickness and height of the fins 2 can be varied within a larger range than is possible using a conventional processes such as extrusion process.

Also, the process according to the embodiments produces heat sinks faster than the processes of producing an extrusion heat sink, folder type and bonded type heat sink according to the prior art and at lower cost.

Further, compared with the prior art extrusion process, the bottom surface 14 of the substrate 1 will be relatively flat, improving heat transmission thereto. Material usage is more efficient by forming a heat sink according to the present embodiments. Heat sinks according to the present embodiments will be more compact, lighter as less material is necessary to produce them, compared with prior art heat sinks having comparable functionality. The fins can be made thinner than is possible in the extrusion process. Also, no rivets or other joining means are required to connect the fins to the substrate, thereby improving the conductivity of the heat sink and more reliable. The cost is also lower because no additional joining process is needed.

1. A method of forming a heat sink, including forming a fin for dissipating heat by separating a length of material from a substrate while leaving the proximal end attached to the substrate.

2. A method according to claim 1, wherein the fin is arcuate or planar.

3. A method according to claim 1 or 2, wherein the fin extends generally perpendicularly to the plane of the substrate.

4. A method according to claim 1, 2 or 3, including forming a ridge in the surface of the substrate for engagement with a cutting tool to form the fin.

5. A method according to claim 4, wherein the ridge forms the distal end of the fin.

6. A method according to any one of the preceding claims, wherein the fin is formed by single or progressive stamping processes by using the single or progressive die tooling.

7. A method according to any one of the preceding claims, including forming a plurality of said fins on the substrate.

8. A method according to claim 7, wherein said plurality of said fins are formed in a series of spaced apart rows.

9. A heat sink having a substrate and a plurality of fins for dissipating heat integrally formed therewith.

10. A heat sink according to claim 9, wherein each fin is a single layer of material extending from the substrate.

11. A heat sink according to claim 9 or 10, wherein the substrate comprises aluminium or copper.

12. A method of forming a heat sink, substantially as hereinbefore described with reference to any one of or combination of the accompanying drawings.

13. A heat sink substantially as hereinbefore described with reference to and/or substantially as illustrated in any one of or any combination of the accompanying drawings.
